(19) United States
(12) Patent Application Publication
(10) Pub. No.: US 2025/0105579 A1
(43) Pub. Date: Mar. 27, 2025

(54) LIGHT BEAM PROCESSOR

(71) Applicant: WuHan Raycus Fber Laser Technologies Co., Ltd, Wuhan, Hubei (CN)

(72) Inventors: Muyao WANG, Wuhan, Hubei (CN); Dapeng YAN, Wuhan, Hubei (CN); Haotian JIA, Wuhan, Hubei (CN); Haowei HU, Wuhan, Hubei (CN); Jianhong SHI, Wuhan, Hubei (CN)

(73) Assignee: WuHan Raycus Fber Laser Technologies Co., Ltd, Wuhan, Hubei (CN)

(21) Appl. No.: 18/728,127

(22) PCT Filed: Dec. 27, 2022
(86) PCT No.: PCT/CN2022/142326

§ 371 Date: Jul. 11, 2024

(30) Foreign Application Priority Data
Jan. 11, 2022 (CN) 202210024278.7

(51) Int. Cl. H01S 3/067; H01S 3/04; H01S 3/094; H01S 3/1055; H01S 3/16

(52) U.S. Cl. CPC H01S 3/0675; H01S 3/0405; H01S 3/06716; H01S 3/094011; H01S 3/094069; H01S 3/1055; H01S 3/1618

(57) ABSTRACT

A light beam processor includes a first light beam amplifying apparatus, a second light beam amplifying apparatus, and a light source generating apparatus. The light source generating apparatus is configured to emit a light source beam to the first light beam amplifying apparatus. The first light beam amplifying apparatus is configured to perform an initial amplification on the light source beam to obtain an amplified light beam. The second light beam amplifying apparatus is configured to perform a secondary amplification on the amplified light beam to obtain a target light beam. The target light beam is used as an output light beam of the light beam processor.

The present disclosure claims priority to Chinese Patent Application No. CN202210024278.7, filed in the China National Intellectual Property Administration on Jan. 11, 2022, entitled “LIGHT BEAM PROCESSOR”, the disclosure of which is incorporated herein by reference in its entirety.

### TECHNICAL FIELD

The present disclosure relates to a light beam processor field, and more particularly, to a light beam processor.

### BACKGROUND

With the development of optical technology, a light beam that meets certain requirements is required for processes in more and more production scenes. As the requirement for process precision increases, parameters of the light beam used are also becoming more and more demanding. For example, in many production scenes, a higher power light beam needs to be used to meet the requirement of process precision.

### SUMMARY

### Technical Problem

Currently used light beam generating devices generally generate a light beam of a desired parameter through reflection of the light beam by a resonant cavity. However, the obtained parameters of the light beam may be affected by the size of the resonant cavity. Generally, the longer the cavity is, the larger the power of the light beam is. When it is desired to generate a light beam of a particular wavelength and frequency, the character of the light beam requires a shorter length of the resonant cavity. In this case, the shorter length of the resonant cavity results in a lower power of the generated light beam, and a significant thermal effect of the light beam, which limits the generated power of the light beam.

### Technical Solution for Problem

### Technical Solution

An embodiment of the present application provides a light beam processor including a first light beam amplifying apparatus, a second light beam amplifying apparatus and a light source generating apparatus, the first light beam amplifying apparatus including a first light beam reflecting unit, a first light beam amplifying unit and a second light beam reflecting unit, wherein a parameter of an emission peak of the first light beam amplifying apparatus matches a parameter of an absorption peak of the second light beam amplifying apparatus, the first light beam reflecting unit is connected to the first light beam amplifying unit, the first light beam amplifying unit is connected to the second light beam amplifying apparatus, the second light beam amplifying apparatus is connected to the second light beam reflecting unit, and the light source generating apparatus is connected to the first light beam amplifying unit;
the light source generating apparatus is configured to emit a light source beam to the first light beam amplifying apparatus;
the first light beam amplifying apparatus is configured to perform an initial amplification on the light source beam to obtain an amplified light beam; and
the second light beam amplifying apparatus is configured to perform a secondary amplification on the amplified light beam to obtain a target light beam, wherein the target light beam is used as an output light beam of the light beam processor.

### Beneficial Effect of the Invention

### Beneficial Effect

An embodiment of the present application provides a light beam processor including a first light beam amplifying apparatus, a second light beam amplifying apparatus and a light source generating apparatus, the first light beam amplifying apparatus including a first light beam reflecting unit, a first light beam amplifying unit and a second light beam reflecting unit, wherein a parameter of an emission peak of the first light beam amplifying apparatus matches a parameter of an absorption peak of the second light beam amplifying apparatus, the first light beam reflecting unit is connected to the first light beam amplifying unit, the first light beam amplifying unit is connected to the second light beam amplifying apparatus, the second light beam amplifying apparatus is connected to the second light beam reflecting unit, and the light source generating apparatus is connected to the first light beam amplifying unit; the light source generating apparatus is configured to emit a light source beam to the first light beam amplifying apparatus; the first light beam amplifying apparatus is configured to perform an initial amplification on the light source beam to obtain an amplified light beam; and the second light beam amplifying apparatus is configured to perform a secondary amplification on the amplified light beam to obtain a target light beam, wherein the target light beam is used as an output light beam of the light beam processor. That is, the light beam processor includes the first light beam amplifying apparatus, the second light beam amplifying apparatus, and the light source generating apparatus. First, the light source generating apparatus generates the light source beam, and the light source beam is input to the first light beam amplifying apparatus for perform the initial amplification to obtain the amplified light beam. By matching the parameter of the emission peak of the first light beam amplifying apparatus with the parameter of the absorption peak of the second light beam amplifying apparatus, the second light beam amplifying apparatus has the highest light absorption efficiency for light emitted by the first light beam amplifying apparatus. The amplified light beam oscillates back and forth between the resonant cavity formed by the first light beam reflecting unit and the second light beam reflecting unit in the first light beam amplifying apparatus. The amplified light beam oscillating back and forth repeatedly passes through the second light beam amplifying apparatus for the secondary amplification to obtain the target light beam. With the above-described method, the problem in the related art that power of a light beam generated by a light beam generating apparatus is lower is solved, and a technical effect of improving the power of the light beam generated by the light beam generating apparatus is achieved.

### BRIEF DESCRIPTION OF THE DRAWINGS

### Drawings Illustration

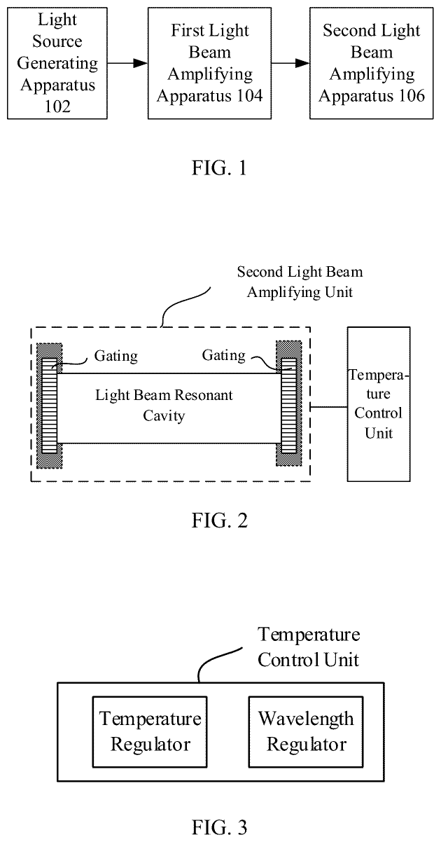

FIG. 1 is a block diagram of a light beam processor according to an embodiment of the present disclosure;

FIG. 2 is a block diagram of a second light beam amplifying apparatus according to an embodiment of the present disclosure;

FIG. 3 is a schematic block diagram of a principle structure of a temperature control unit according to an embodiment of the present disclosure;

FIG. 4 is a block diagram of a light source generating apparatus according to an embodiment of the present disclosure;

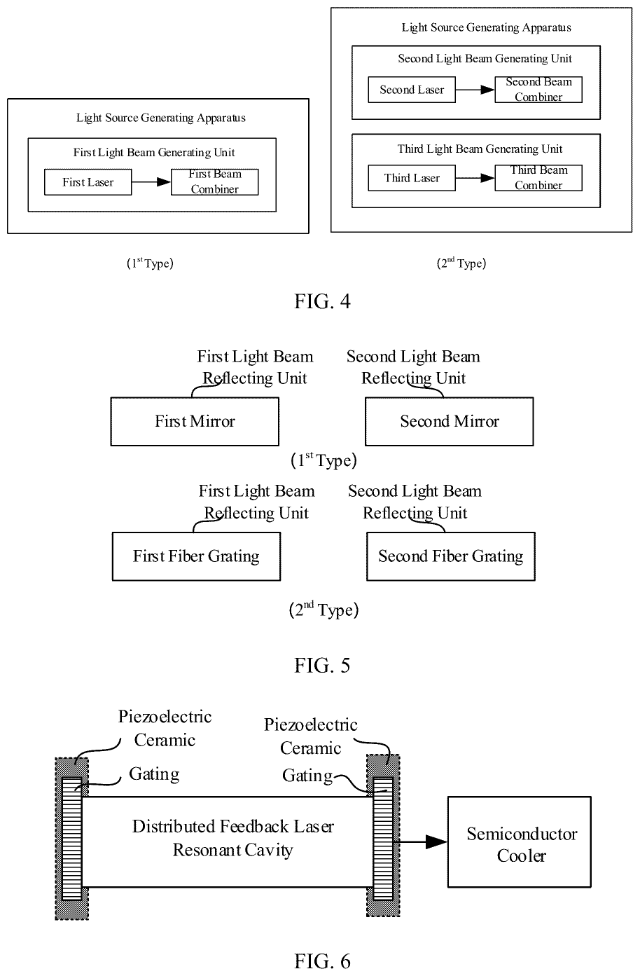

FIG. 5 is a block diagram of a first light beam reflecting unit and a second light beam reflecting unit according to an embodiment of the present disclosure;

FIG. 6 is a block diagram of a second light beam amplifying apparatus according to an embodiment of the present disclosure;

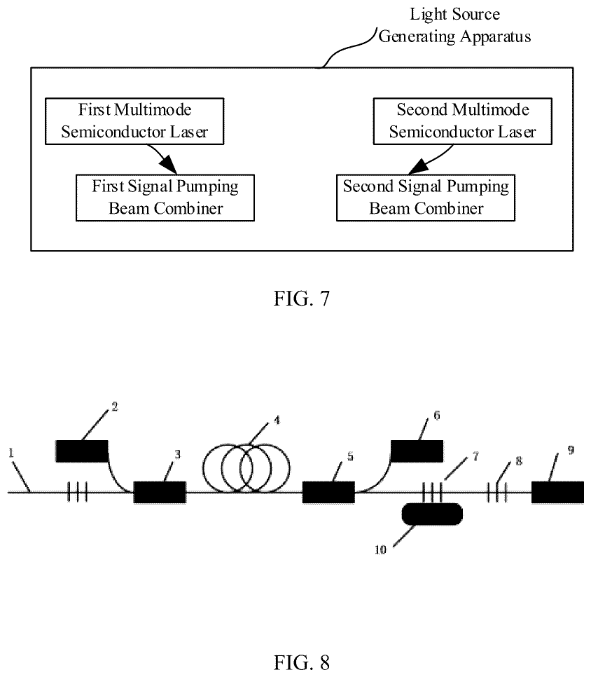

FIG. 7 is a schematic block diagram of a light source generating apparatus according to an embodiment of the present disclosure; and

FIG. 8 is a schematic diagram of a DFB laser according to an alternative embodiment of the present disclosure.

### DETAILED DESCRIPTION

### Detailed Description of the Invention

In order that the embodiments of the present disclosure may be better understood by those skilled in the art, reference will now be made, in conjunction with the accompanying drawings, to some of embodiments of the present disclosure, which will be described more clearly and completely, and it will be apparent that the described embodiments are merely a part of, and not all, the embodiments of the present disclosure. Based on the embodiments of the present disclosure, all other embodiments obtained by a person of ordinary skill in the art without involving any inventive effort shall fall within the scope of the present disclosure.

It is to be noted that the terms “first”, “second”, etc. in the specification and claims and the above-mentioned the accompanying drawings of the present disclosure are used to distinguish similar objects and need not be used to describe a particular order or sequence. It should be understood that the data so used are interchangeable, where appropriate, so that the embodiments of the present disclosure described herein described herein may be implemented in an order other than those illustrated or described herein. In addition, the terms “including” and “having” and any variations thereof, are intended to cover non-exclusive encompassing. For example, a process, method, system, product or apparatus including a series of steps or units need not be limited to those steps or units that are clearly listed, but may include other steps or units that are not clearly listed or are inherent to the process, method, product or apparatus.

In the present embodiment, a light beam processor is provided. FIG. 1 is a block diagram of a light beam processor according to an embodiment of the present disclosure. As shown in FIG. 1, the light beam processor includes a light source generating apparatus 102, a first light beam amplifying apparatus 104, and a second light beam amplifying apparatus 106. The first light beam amplifying apparatus 104 includes a first light beam reflecting unit 104-2, a first light beam amplifying unit 104-4, and a second light beam reflecting unit 104-6. The first light beam amplifying unit 104-4 is connected to the first light beam amplifying unit 104-4, the first light beam amplifying unit 104-4 is connected to the second light beam amplifying apparatus 106, the second light beam amplifying apparatus 106 is connected to the second light beam reflecting unit 104-6, and the light source generating apparatus 102 is connected to the first light beam amplifying unit 104-4.

The light source generating apparatus 102 is configured to emit a light source beam to the first light beam amplifying apparatus;

The first light beam amplifying apparatus 104 is configured to perform an initial amplification on the light source beam to obtain an amplified light beam;

The second light beam amplifying apparatus 106 is configured to perform the secondary amplification on the amplified light beam to obtain a target light beam. The target light beam is used as an output light beam of the light beam processor.

According to the above embodiment, the light beam processor includes a first light beam amplifying apparatus, a second light beam amplifying apparatus, and a light source generating apparatus. First, the light source generating apparatus generates a light source beam, and inputs the light source beam into the first light beam amplifying apparatus for initial amplification to obtain an amplified light beam. By matching a parameter of an emission peak of the first light beam amplifying apparatus with a parameter of an absorption peak of the second light beam amplifying apparatus, the second light beam amplifying apparatus has the highest light absorption efficiency for light emitted by the first light beam amplifying apparatus. The amplified light beam oscillates between the resonant cavity formed by a first light beam reflecting unit and a second light beam reflecting unit in the first light beam amplifying apparatus, and the oscillating amplified light beam repeatedly passes through the second light beam amplifying apparatus for secondary amplification to obtain a target light beam. With the above-described method, the problem in the related art that power of a light beam generated by a light beam generating apparatus is lower is solved, and a technical effect of improving the power of the light beam generated by the light beam generating apparatus is achieved.

Alternatively, in the present embodiment, the light source generating apparatus may include, but is not limited to, any device that may generate a light beam of a specific wavelength, such as a laser including a solid laser, a gas laser, a dye laser, a semiconductor laser, a fiber laser, and a free electron laser.

Alternatively, in the present embodiment, the first light beam amplifying apparatus may, but is not limited to, any apparatus for amplifying the power of the light source beam to obtain an amplified light beam, and oscillating the amplified light beam in the resonant cavity. For example, the first light beam amplifying apparatus may an apparatus for coupling the light source beam into a pump gain optical fiber of the first light beam amplifying apparatus through a beam combiner, and absorbing the light source beam by the pump gain optical fiber, and amplifying the amplified light beam to obtain an amplified light beam, and making the amplified light beam oscillate back and forth between the resonant cavity formed by a fiber grating.

Alternatively, in the present embodiment, the second light beam amplifying apparatus may, but is not limited to, a device configured to perform the secondary amplification of the amplified light beam to realize operation of a single-longitudinal-mode of a single-frequency fiber laser, and output a dynamic single-longitudinal-mode narrow-linewidth light beam. For example, a phase-shifted grating is inscribed directly on the gain fiber medium by UV light to form the resonant cavity. The selection of the laser wavelength may be realized only by inscribing one grating on the gain fiber, which avoids the welding of the heterogeneous fiber with respect to the DBR-type single-frequency fiber laser. When the longitudinal mode spacing of the resonant cavity is greater than the reflection bandwidth of the fiber grating, stable operation of the single-longitudinal-mode is realized.

Alternatively, in the present embodiment, in order to ensure the highest light absorption efficiency of the second light beam amplifying apparatus for light emitted by the first light beam amplifying apparatus, it is required that the parameter of the emission peak of the first light beam amplifying apparatus matches the parameter of the absorption peak of the second light beam amplifying apparatus, which may means, but not limited to, the parameter of the emission peak of the gain optical fiber of the first light beam amplifying apparatus matching the parameter of the absorption peak of the gain optical fiber of the second light beam amplifying apparatus. For example, the gain optical fiber of the resonant cavity of the second light beam amplifying apparatus is placed in the resonant cavity of the first light beam amplifying apparatus, and the amplified light beam of the oscillation cycle in the resonant cavity and the characteristic that the emission peak of the gain optical fiber of the first light beam amplifying apparatus correspond to the absorption peak of the gain optical fiber in the resonant cavity of the second light beam amplifying apparatus are used, so that the fiber laser has a higher output power.

Alternatively, in the present embodiment, the first light beam reflecting unit and the second light beam reflecting unit form a resonant cavity, so that the selection of the laser wavelength may be realized. The selection of the laser wavelength may be realized by, but is not limited to, inscribing a phase-shifted grating on the gain fiber by using ultraviolet light to form the resonant cavity. The laser wavelength may be selected merely by inscribing a grating on the gain fiber, which avoids the welding of the heterogeneous fiber with respect to the DBR-type single-frequency fiber laser. For example, The DFB resonant cavity is located in a resonant cavity formed by the first light beam reflecting unit and the second light beam reflecting unit, and the amplified light beam is repeatedly passed through the DFB gain optical fiber, so that the DFB gain optical fiber sufficiently absorbs the amplified light beam circulated in the cavity, thereby generating a high-power laser.

FIG. 2 is a block diagram of a second light beam amplifying apparatus according to an embodiment of the present disclosure. As shown in FIG. 2, in an exemplary embodiment, the second light beam amplifying apparatus includes a second light beam amplifying unit and a temperature control unit. The second light beam amplifying unit includes a light beam resonant cavity formed by a grating. The light beam resonant cavity is connected with the first light beam amplifying unit and the second light beam reflecting unit. The temperature control unit is connected to the light beam resonant cavity. The temperature control unit is configured to control the temperature of the light beam resonant cavity to be within an operating temperature range. The light beam resonant cavity is configured to perform the secondary amplification on the amplified light beam in an operating temperature range to obtain a target light beam.

Alternatively, in the present embodiment, the light beam resonant cavity may include, but is not limited to, any structure or configuration in which a standing wave of a specific wavelength may be generated, for example, a fiber grating or a metal wall. A light beam oscillates back and forth between reflection units to generate and reinforce a light beam of a specific frequency, and the above reflection units form the resonant cavity. The standing wave of the specific wavelength is generated by controlling a linearity condition of the resonant cavity, and the standing wave of the remaining wavelengths are suppressed and weakened. For example, a phase-shifted grating is inscribed directly on the gain fiber medium by UV light to form the resonant cavity, and the selection of the laser wavelength may be realized only by inscribing one grating on the gain fiber.

Alternatively, in the present embodiment, the temperature control unit may include, but is not limited to, any device having a temperature adjustment function for controlling the temperature of the light beam resonant cavity to be within the operating temperature range. For example, the temperature of the resonance cavity may be controlled within a suitable range by means of, but not limited to, a semiconductor cooler (Thermo Electric Cooler, TEC) temperature control.

FIG. 3 is a schematic block diagram of a principle structure of a temperature control unit according to an embodiment of the present disclosure. As shown in FIG. 3, in an exemplary embodiment, the temperature control unit includes: a temperature regulator and a wavelength regulator, where the temperature regulator is connected to the light beam resonant cavity and the wavelength regulator is connected to the grating of the light beam resonant cavity. The temperature regulator is configured to control the temperature of the light beam resonant cavity to be within an operating temperature range. The wavelength adjuster is configured to adjust the spacing of the grating in the light beam resonant cavity.

Alternatively, in the present embodiment, the temperature regulator may, but is not limited to, adjust the temperature by the TEC temperature control. The temperature of the light beam resonant cavity is controlled to be within the operating temperature range, so as to prevent the occurrence of mode instability and mode hopping phenomenon in the DFB resonant cavity due to excessively high temperature, thereby achieving the high power output of the fiber laser.

Alternatively, in the present embodiment, the wavelength regulator may include, but is not limited to, any device capable of adjusting the spacing of the fiber grating. For example, the DFB resonant cavity is sensitive to the temperature. To ensure that the temperature in the DFB resonant cavity is kept in a certain range, the temperature of the resonant cavity is controlled to be within a proper range by the TEC temperature control, and the spacing of the fiber grating is accurately modulated by PZT tuning.

FIG. 4 is a block diagram of a light source generating apparatus according to an embodiment of the present disclosure. As shown in FIG. 4 (1^{st} type), in an exemplary embodiment, the light source generating apparatus includes a first light beam generating unit. The first light beam generating unit is connected to a side of the first light beam amplifying unit connected to the first light beam reflecting unit, or the first light beam generating unit is connected to a side of the first light beam amplifying unit connected to the second light beam amplifying apparatus. The first light beam generating unit is configured to transmit the light source beam to the first light beam amplifying apparatus.

Alternatively, in the present embodiment, the light source generating apparatus may include, but is not limited to, any device having a function of emitting a light source beam, for example, a solid-state laser, a gas laser, a dye laser, a semiconductor laser, a fiber laser, and a free-electron laser.

In an exemplary embodiment, the first light beam generating unit includes a first laser and a first beam combiner. The first laser is connected to the first beam combiner. The first beam combiner is connected to a side of the first light beam amplifying unit connected to the first light beam reflecting unit, or the first beam combiner is connected to a side of the first light beam amplifying unit connected to the second light beam amplifying apparatus. The first laser is configured to generate the light source beam. The first beam combiner is configured to transmit the light source beam to the first light beam amplifying unit.

Alternatively, in the present embodiment, the beam combiner may include, but is not limited to, any apparatus configured to combine the light source beam into the first light beam amplifying unit, such as a power beam combiner and a pump beam combiner.

In an exemplary embodiment, the light source generating apparatus includes a second light beam generating unit and a third light beam generating unit. The second light beam generating unit is connected to a side of the first light beam amplifying unit connected to the first light beam reflecting unit, and the third light beam generating unit is connected to a side of the first light beam amplifying unit connected to the second light beam amplifying apparatus. The second light beam generating unit is configured to emit a first light beam to the first light beam amplifying apparatus. The third light beam generating unit is configured to emit a second light beam to the first light beam amplifying apparatus. The light source beam includes the first light beam and the second light beam.

Alternatively, in the present embodiment, in addition to the above-described dual-end pumping connection, the light source generating apparatus may use, but is not limited to, a forward pumping connection, that is, the light source generating apparatus includes one of the second light beam generating unit and the third light beam generating unit, the second light beam generating unit is connected to a side of the first light beam amplifying unit connected to the first light beam reflecting unit, and the third light beam generating unit is connected to a side of the first light beam amplifying unit connected to the second light beam amplification device.

As shown in FIG. 4 (2^{nd} type), in an exemplary embodiment, the second light beam generating unit includes a second laser and a second beam combiner, and the third light beam generating unit includes a third laser and a third beam combiner. The second laser is connected to the second beam combiner. The second beam combiner is connected to the side of the first light beam amplifying unit connected to the first light beam reflecting unit. The third laser is connected to the third beam combiner. The third beam combiner is connected to the side of the first light beam amplifying unit connected to the second light beam amplifying apparatus. The second laser is configured to generate the first light beam. The second beam combiner is configured to transmit the first light beam to the first light beam amplifying unit. The third laser is configured to generate a second light beam. The third beam combiner is configured to transmit the second light beam to the first light beam amplifying unit.

Alternatively, in the present embodiment, the second light beam generating unit and the third light beam generating unit are connected by, but is not limited to, dual-end pumping of an intracavity multi-mode semiconductor laser, so that sufficient pumping energy is supplied to the resonant cavity of the first light beam amplifying apparatus and a certain unnecessary loss is reduced.

In an exemplary embodiment, the light beam processor further includes a light beam stripper and a light beam outputter. The light beam stripper is between and connected with the second light beam reflecting unit and the light beam outputter. The light beam stripper is configured to select the target light beam from the input light beam and transmitting the target light beam to the light beam outputter. The light beam output device is configured to output the target light beam.

Alternatively, in the present embodiment, the light beam stripper may include, but is not limited to, any apparatus for removing cladding light from an optical fiber, such as a light leakage apparatus including a transparent coated, sheathed material. For example, the light beam stripper is added behind the resonant cavity to extract the amplified beam that is not fully absorbed by the DFB resonant cavity, to ensure the beam quality and system stability of the target beam output from the single-frequency fiber laser.

FIG. 5 is a block diagram of a first light beam reflecting unit and a second light beam reflecting unit according to an embodiment of the present disclosure. As shown in FIG. 5, in an exemplary embodiment, the first light beam reflecting unit includes a first mirror and the second light beam reflecting unit includes a second mirror. Alternatively, the first light beam reflecting unit includes a first reflection grating, and the second light beam reflecting unit includes a second reflection grating.

Alternatively, in the present embodiment, the first reflection grating and the second reflection grating are used to form the resonant cavity, and the first reflection grating and the second reflection grating may include, but are not limited to, a phase-shifted grating inscribed directly on the gain fiber medium by UV light to form the resonant cavity, and the selection of the laser wavelength may be realized only by inscribing one grating on the gain fiber, which avoids welding of the heterogeneous fiber with respect to the DBR-type single-frequency fiber laser.

FIG. 6 is a block diagram of a second light beam amplifying apparatus according to an embodiment of the present disclosure. As shown in FIG. 6, in an exemplary embodiment, the first light beam reflecting unit includes a first fiber grating, the first light beam amplifying unit includes a gain fiber, and the second light beam reflecting unit includes a second fiber grating. The second light beam amplifying apparatus includes a distributed feedback laser resonant cavity, a semiconductor cooler, and a piezoelectric ceramic. The distributed feedback laser resonant cavity is between and connected with the gain fiber and the second fiber grating. The semiconductor cooler is connected with the distributed feedback laser resonant cavity, and the piezoelectric ceramic is connected with the grating of the distributed feedback laser resonant cavity.

FIG. 7 is a schematic block diagram of a light source generating apparatus according to an embodiment of the present disclosure. As shown in FIG. 7, the light source generating apparatus includes a first multimode semiconductor laser, a first signal pumping beam combiner, a second multimode semiconductor laser, and a second signal pumping beam combiner. The first multimode semiconductor laser is connected to the first signal pumping beam combiner. The first signal pumping beam combiner is between and connected with the first fiber grating and the gain fiber. The second multimode semiconductor laser is connected to the second signal pumping beam combiner, and the second signal pumping beam combiner is between and connected with the gain fiber and the distributed feedback laser resonant cavity.

Alternatively, in the present embodiment, the gain optical fiber may include, but is not limited to, an optical fiber formed by a gain medium. Pump light emitted from the pump source is coupled into the gain medium through a mirror. Since the gain medium is a rare-earth-doped optical fiber, the pump light is absorbed by the gain medium, and the rare-earth ions having absorbed photon energy are subjected to energy level transition to cause the population inversion. The reversed particles such as the ions pass through the resonant cavity, transition from the excited state to the ground state to release energy, and thus a stable laser is output. In addition to ytterbium-doped fibers, pump gain fibers may further be other doped fibers such as fibers doped with the common rare earth ion (such as erbium-doped fibers, thulium-doped fibers, or the like).

For a better understanding of the light beam processor, the light beam processor will be described below in connection with an alternative embodiment, but it is not intended to limit the technical solution of the embodiments of the present disclosure.

The light source generating apparatus may be a distributed feedback (DFB) laser. FIG. 8 is a schematic diagram of a DFB laser according to another embodiment of the present disclosure. As shown in FIG. 8, in the present alternative embodiment, provided is a structure of a DFB laser including a first pump fiber grating 1, a multimode semiconductor laser 2, a first signal pump beam combiner 3, a pump gain fiber 4, a second signal pump beam combiner 5, a multimode semiconductor laser 6, a DFB resonant cavity 7, a second pump fiber grating 8, a mode stripper 9, and a temperature control system 10.

A side of The first signal pump combiner 3 and a side of the second signal pump combiner 5 are connected to opposite ends of the pump gain optical fiber 4, respectively. The other side of the first signal pump combiner 3 is connected to the first pump optical fiber grating 1 and the multimode semiconductor laser 2. The other side of the pump gain optical fiber 4 is connected to a side of the DFB resonant cavity 7 and the multimode semiconductor laser 6. The other side of the DFB resonant cavity 7 is connected to a side of the second pump optical fiber grating 8. The peeler 9 is connected to the other side of the second pump optical fiber grating 8. The temperature control system 10 is connected to the DFB resonant cavity 7.

On one aspect, by the above-mentioned DFB laser, the total energy of the pump light is increased by the dual-end pumping technique without reducing the pumping efficiency, that is, the pump light is generated by using the multimode semiconductor laser 2 and the multimode semiconductor laser 6, and the pump light enters the pump gain optical fiber 4 through the corresponding signal pump combiner.

On the other aspect, after the pump gain fiber 4 absorbs the pump light generated from the multimode semiconductor laser 2 and the multimode semiconductor laser 6, the pump light is initially amplified to obtain an amplified light beam.

Finally, the amplified light beam is reflected back and forth between the first pump fiber grating 1 and the second pump fiber grating 8, is repeatedly absorbed by the gain fiber in the DFB resonant cavity 7, and is performed the secondary amplification to obtain the target light beam. In the secondary amplification process, the temperature control system 10 continuously acts on the DFB resonant cavity 7 to avoid the accumulation of heat generated by the laser, thereby causing the occurrence of mode instability or mode hopping phenomenon in the DFB resonant cavity, and deteriorating optical parameters such as the line width and frequency noise of the single-frequency fiber laser.

The foregoing description is merely a preferred embodiment of the present disclosure, and is not intended to limit the present disclosure. Various modifications and variations of the present disclosure will become apparent to those skilled in the art. Any modifications, equivalents, improvements according to the principles of the present disclosure are intended to be included within the scope of the present disclosure.

What is claimed is:

1. A light beam processor comprising a first light beam amplifying apparatus, a second light beam amplifying apparatus and a light source generating apparatus, the first light beam amplifying apparatus comprising a first light beam reflecting unit, a first light beam amplifying unit and a second light beam reflecting unit, wherein a parameter of an emission peak of the first light beam amplifying apparatus matches a parameter of an absorption peak of the second light beam amplifying apparatus, the first light beam reflecting unit is connected to the first light beam amplifying unit, the first light beam amplifying unit is connected to the second light beam amplifying apparatus, the second light beam amplifying apparatus is connected to the second light beam reflecting unit, and the light source generating apparatus is connected to the first light beam amplifying unit;
the light source generating apparatus is configured to emit a light source beam to the first light beam amplifying apparatus;
the first light beam amplifying apparatus is configured to perform an initial amplification on the light source beam to obtain an amplified light beam, wherein the first light beam reflecting unit and the second light beam reflecting unit are used to form a resonant cavity to select a laser wavelength; and
the second light beam amplifying apparatus is configured to perform a secondary amplification on the amplified light beam to obtain a target light beam, wherein the target light beam is used as an output light beam of the light beam processor.

2. The light beam processor of claim 1, wherein the resonant cavity is formed by the first light beam reflecting unit and the second light beam reflecting unit by means of inscribing a phase shift grating by UV light to select the laser wavelength.

3. The light beam processor of claim 1, wherein the second light beam amplifying apparatus includes an apparatus configured to perform the secondary amplification on the amplified light beam to realize operation of single-longitudinal-mode of a single-frequency fiber laser, and output a dynamic single-longitudinal-mode narrow-linewidth light beam.

4. The light beam processor of claim 1, wherein the second light beam amplifying apparatus comprises a second light beam amplifying unit and a temperature control unit, wherein the second light beam amplifying unit comprises a light beam resonant cavity formed by a grating, the light beam resonant cavity is connected with the first light beam amplifying unit and the second light beam reflecting unit, and the temperature control unit is connected to the light beam resonant cavity;
the temperature control unit is configured to control temperature of the light beam resonant cavity to be within an operating temperature range; and
the light beam resonant cavity is configured to perform the secondary amplification on the amplified light beam in the operating temperature range to obtain the target light beam.

5. The light beam processor of claim 4, wherein the light beam resonant cavity is formed by inscribing a phase shift grating by UV light.

6. The light beam processor of claim 4, wherein a single-longitudinal-mode is stably operated when a longitudinal mode spacing of the light beam resonant cavity is greater than a reflection bandwidth of the fiber grating.

7. The light beam processor of claim 4, wherein the temperature control unit is a semiconductor refrigerator.

8. The light beam processor of claim 4, wherein the temperature control unit comprises a temperature regulator and a wavelength regulator, wherein the temperature regulator is connected to the light beam resonant cavity and the wavelength regulator is connected to a grating of the light beam resonant cavity;
the temperature regulator is configured to control the temperature of the light beam resonant cavity to be within the operating temperature range; and
the wavelength adjuster is configured to adjust a spacing of the grating of the light beam resonant cavity.

9. The light beam processor of claim 1, wherein the light source generating apparatus comprises a first light beam generating unit, wherein the first light beam generating unit is connected to a side of the first light beam amplifying unit connected to the first light beam reflecting unit, or the first light beam generating unit is connected to a side of the first light beam amplifying unit connected to the second light beam amplifying apparatus; and
the first light beam generating unit is configured to transmit the light source beam to the first light beam amplifying apparatus.

10. The light beam processor of claim 9, wherein the first light beam generating unit comprises a first laser and a first beam combiner, wherein the first laser is connected to the first beam combiner; the first beam combiner is connected to a side of the first light beam amplifying unit connected to the first light beam reflecting unit, or the first beam combiner is connected to a side of the first light beam amplifying unit connected to the second light beam amplifying apparatus;
the first laser is configured to generate the light source beam; and
the first beam combiner is configured to transmit the light source beam to the first light beam amplifying unit.

11. The light beam processor of claim 1, wherein the light source generating apparatus comprises a second light beam generating unit and a third light beam generating unit, wherein the second light beam generating unit is connected to a side of the first light beam amplifying unit connected to the first light beam reflecting unit, and the third light beam generating unit is connected to a side of the first light beam amplifying unit connected to the second light beam amplifying apparatus;
the second light beam generating unit is configured to emit a first light beam to the first light beam amplifying apparatus; and
the third light beam generating unit is configured to emit a second light beam to the first light beam amplifying apparatus; and
wherein the light source beam comprises the first light beam and the second light beam.

12. The light beam processor of claim 11, wherein the second light beam generating unit comprises a second laser and a second beam combiner, and the third light beam generating unit comprises a third laser and a third beam combiner, wherein the second laser is connected to the second beam combiner, the second beam combiner is connected to the side of the first light beam amplifying unit connected to the first light beam reflecting unit, the third laser is connected to the third beam combiner, and the third beam combiner is connected to the side of the first light beam amplifying unit connected to the second light beam amplifying apparatus;
the second laser is configured to generate the first light beam, and the second beam combiner is configured to transmit the first light beam to the first light beam amplifying unit; and
the third laser is configured to generate a second light beam; and the third beam combiner is configured to transmit the second light beam to the first light beam amplifying unit.

13. The light beam processor of claim 11, wherein the second light beam generating unit and the third light beam generating unit are connected by dual-end pumping of an intracavity multi-mode semiconductor laser.

14. The light beam processor of claim 1, wherein the light beam processor further comprises a light beam stripper and a light beam outputter, wherein the light beam stripper is connected with the second light beam reflecting unit and the light beam outputter;
the light beam stripper is configured to select the target light beam from input light beam and transmit the target light beam to the light beam outputter; and
the light beam output device is configured to output the target light beam.

15. The light beam processor of claim 1, wherein the first light beam reflecting unit comprises a first mirror and the second light beam reflecting unit comprises a second mirror.

16. The light beam processor of claim 1, wherein the first light beam reflecting unit comprises a first reflection grating and the second light beam reflecting unit comprises a second reflection grating.

17. The light beam processor of claim 1, wherein the first light beam reflecting unit comprises a first fiber grating, the first light beam amplifying unit comprises a gain fiber, and the second light beam reflecting unit comprises a second fiber grating;
the second light beam amplifying apparatus comprises a distributed feedback laser resonant cavity, a semiconductor cooler, and a piezoelectric ceramic, wherein the distributed feedback laser resonant cavity is connected with the gain fiber and the second fiber grating, the semiconductor cooler is connected to the distributed feedback laser resonant cavity, and the piezoelectric ceramic is connected to a grating of the distributed feedback laser resonant cavity; and
the light source generating apparatus comprises a first multimode semiconductor laser, a first signal pumping beam combiner, a second multimode semiconductor laser, and a second signal pumping beam combiner, wherein the first multimode semiconductor laser is connected to the first signal pumping beam combiner, the first signal pumping beam combiner is connected with the first fiber grating and the gain fiber, the second multimode semiconductor laser is connected to the second signal pumping beam combiner, and the second signal pumping beam combiner is connected with the gain fiber and the distributed feedback laser resonant cavity.

18. The light beam processor of claim 17, wherein the gain fiber is an ytterbium-doped fiber.

19. The light beam processor of claim 17, wherein the light source generating apparatus is a distributed feedback laser.

20. The light beam processor of claim 1, wherein a parameter of an emission peak of the gain fiber of the first light beam amplifying apparatus matches a parameter of an absorption peak of the gain fiber of the second light beam amplifying apparatus.
